(19) United States
(12) Patent Application Publication
(10) Pub. No.: US 2005/0258432 A1
(43) Pub. Date: Nov. 24, 2005

(54) Method for increasing optical output of semiconductor led using pulsation current and a driving unit of the semiconductor led using the method

(75) Inventor: Jae-hee Cho, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electro-mechanics Co., Ltd., Gyeonggi-do (KR)

(21) Appl. No.: 10/981,499

(22) Filed: Nov. 5, 2004

(30) Foreign Application Priority Data
May 12, 2004 (JP) 10-2004-0033378

(51) Int. Cl. H01L 27/15

(52) U.S. Cl. 257/79

(57) ABSTRACT

Provided is a method of increasing an optical output of a semiconductor light-emitting device using a pulsation current and a driving unit of the semiconductor light-emitting device using the method. The method includes: applying a pulsation current in which a forward voltage alternates with a reverse voltage to the semiconductor light-emitting device including an n-type semiconductor layer, an active layer, and a p-type semiconductor layer. The driving unit includes: a semiconductor light-emitting device including an n-type semiconductor layer, an active layer, and a p-type semiconductor layer; and a voltage applying unit which applies a pulsation current in which a forward voltage alternates with a reverse voltage to the semiconductor light-emitting device.

### BACKGROUND OF THE INVENTION

This application claims the priority of Korean Patent Application No. 2004-33378, filed on May 12, 2004, in the Korean Intellectual Property Office, the disclosure of which is incorporated herein in its entirety by reference.

1. Field of the Invention

The present invention relates to a method of increasing an optical output of a compound semiconductor light-emitting device (LED) and a driving unit of the compound semiconductor LED, and more particularly, to a method of increasing an optical output of a compound semiconductor LED using a pulsation current and a driving unit of the compound semiconductor LED using the method.

2. Description of the Related Art

Like a light-emitting diode (LED), a semiconductor LED converts an electric signal into light using the characteristics of a compound semiconductor. Such a semiconductor LED device has the advantages of a longer lifespan, a lower drive voltage, and a smaller amount of power consumption than other light emitters. Also, the semiconductor LED has higher response speed and higher impact durability, and may be made compact and light. Such a semiconductor LED may produce light beams of different wavelengths depending on the types and materials of a used semiconductor. Thus, the semiconductor LED may produce light beams of various kinds of wavelengths. In particular, high brightness semiconductor LEDs capable of emitting highly bright light have been developed and widely used due to the improvement of manufacturing techniques and of the structure of the semiconductor LEDs. Moreover, a high brightness semiconductor LED for emitting a blue (B) light has been developed. As a result, natural color can be displayed using high brightness semiconductor LEDs for emitting green (G), red (R), and B beams, respectively.

FIG. 1 is a schematic view for explaining the operation principle of a general semiconductor LED. As shown in FIG. 1, a semiconductor LED 10 has a structure in which an n-type semiconductor layer 12, an active layer 13, and a p-type semiconductor layer 14 are sequentially stacked on a sapphire substrate 11, and an n-type electrode 15 and a p-type electrode 16 are stacked on a portion of the n-type semiconductor layer 12 and the p-type semiconductor layer 14, respectively. When a forward voltage is applied to the semiconductor LED 10 having the above-described structure, electrons in a conduction band of the n-type semiconductor layer 12 transit to re-combine with holes in a valence band of the p-type semiconductor layer 14. As a result, as much light as transition energy is emitted from the active layer 13. The light from the active layer 13 is directly emitted through an upper part of the active layer 13 or is reflected from the p-type electrode 16 and then emitted via the sapphire substrate 11.

Since the semiconductor LED 10 generally has polarity, the semiconductor LED 10 is driven using a direct current (DC) as shown in FIG. 2. This is because the electrons of the n-type semiconductor layer 12 and the holes of the p-type semiconductor layer 14 do not move to the active layer 13, and thus light is not emitted when applied voltages have opposite polarities. However, in a case where a semiconductor LED is driven by applying a DC, electrons have higher mobility than holes. Thus, almost electrons from the n-type semiconductor layer 12 are distributed adjacent to the p-type semiconductor layer 14. This causes emissions efficiency to be lowered.

It is known that the mobility of holes is low in an III-group nitride (mainly a compound related to GaN) semiconductor materials of a semiconductor LED. Nonetheless, since a nitride semiconductor is very stable with respect to optical, electric, and thermal stimuli and may be manufactured so as to produce light within a wide range between a blue area and a purple area, the nitride semiconductor is now noticed. Accordingly, many studies have been made to develop a high efficiency, brightness semiconductor LED which is driven by lower power and generates a small amount of heat using such a nitride semiconductor. Enormous cost and time are invested in such studies, which impose a heavy burden on manufacturers.

### SUMMARY OF THE INVENTION

The present invention provides a method of improving emission efficiency of a semiconductor LED by preventing electrons in an active layer from being biased toward a p-type semiconductor layer.

The present invention also provides a method of further simply increasing an optical output and stability of a compound semiconductor LED at a low cost and a driving unit of the compound semiconductor LED using the method.

According to an aspect of the present invention, there is provided a method of increasing an optical output of a semiconductor light-emitting device, including: applying a pulsation current in which a forward voltage alternates with a reverse voltage to the semiconductor light-emitting device including an n-type semiconductor layer, an active layer, and a p-type semiconductor layer.

An absolute value of the reverse voltage applied to the semiconductor light-emitting device is larger than 0.1V.

It is preferable that a frequency of the pulsation current is at least 1 KHz, and a duty ratio of the pulsation current is within a range between 10% and 90%.

An absolute value of the reverse voltage applied to the semiconductor light-emitting device may be larger than an absolute value of the forward voltage. In this case, a magnitude of the reverse voltage may be smaller than a magnitude of a breakdown voltage of the semiconductor light-emitting device.

The pulsation current is applied to at least two semiconductor light-emitting devices which are connected in parallel so as to have opposite polarity directions.

According to another aspect of the present invention, there is provided a driving unit of a semiconductor light-emitting device including: a semiconductor light-emitting device including an n-type semiconductor layer, an active layer, and a p-type semiconductor layer; and a voltage applying unit which applies a pulsation current in which a forward voltage alternates with a reverse voltage to the semiconductor light-emitting device.

It is preferable that an absolute value of the reverse voltage applied to the semiconductor light-emitting device is larger than 0.1V, and a frequency of the pulsation current is at least 1 KHz.

It is preferable that a duty ratio of the pulsation current is within a range between 10% and 90%.

An absolute value of the reverse voltage applied to the semiconductor light-emitting device may be larger than an absolute value of the forward voltage. In this case, a magnitude of the reverse voltage may be smaller than a magnitude of a breakdown voltage of the semiconductor light-emitting device.

Here, the semiconductor light-emitting device is a nitride-based semiconductor light-emitting device.

According to still another aspect of the present invention, there is provided a driving unit of a semiconductor light-emitting device including: a plurality of semiconductor light-emitting devices including n-type semiconductor layers, active layers, and p-type semiconductor layers; and a voltage applying unit which applies a pulsation current in which a forward voltage alternates with a reverse voltage to the plurality of semiconductor light-emitting devices. Here, at least two of the plurality of semiconductor light-emitting devices are connected in parallel so as to have opposite polarity directions.

A frequency of the pulsation current is at least 1 KHz.

An absolute value of the reverse voltage applied to the pair of light-emitting devices is substantially equal to an absolute value of the forward voltage. A duty ratio of the pulsation current applied to the pair of semiconductor light-emitting devices is substantially 50%.

### BRIEF DESCRIPTION OF THE DRAWINGS

The above and other features and advantages of the present invention will become more apparent by describing in detail exemplary embodiments thereof with reference to the attached drawings in which:

FIG. 1 is a view for showing a layer structure of a conventional compound semiconductor LED;

FIG. 2 is a view for explaining a method of driving the conventional compound semiconductor LED using a DC;

FIG. 3 is a referential view for explaining a general pulsation current;

FIG. 4 is a view for explaining a method of driving a semiconductor LED using a pulsation current not including a reverse voltage;

FIG. 5 is a view for explaining a method of driving a semiconductor LED using a pulsation current including a reverse voltage, according to the present invention;

FIG. 6 is a graph for showing variations of an optical output of the semiconductor LED of the present invention with respect to the magnitude of an applied voltage when an applied pulsation current includes a reverse voltage or does not the inverse voltage;

FIG. 7 is a view for exemplarily showing an energy band for explaining the principle of the present invention using an electron density variation model;

FIGS. 8A through 8C are views for exemplarily showing an energy band for explaining the principle of the present invention using a quantum confined stark effect (QCSE) model;

FIG. 9 is a graph for showing variations of the optical output of the semiconductor LED of the present invention with respect to the magnitude of a reverse voltage;

FIG. 10 is a graph for showing variations of the optical output of the semiconductor LED of the present invention with respect to variations of a frequency of a pulsation current when the pulsation current includes a reverse voltage or does not the reverse voltage;

FIG. 11 is a graph for showing variations of the optical output of the semiconductor LED with respect to variations of a duty ratio of a pulsation current when the pulsation includes a reverse voltage or does not include the reverse voltage; and

FIG. 12 is a view for showing a driving unit of the semiconductor LED of the present invention.

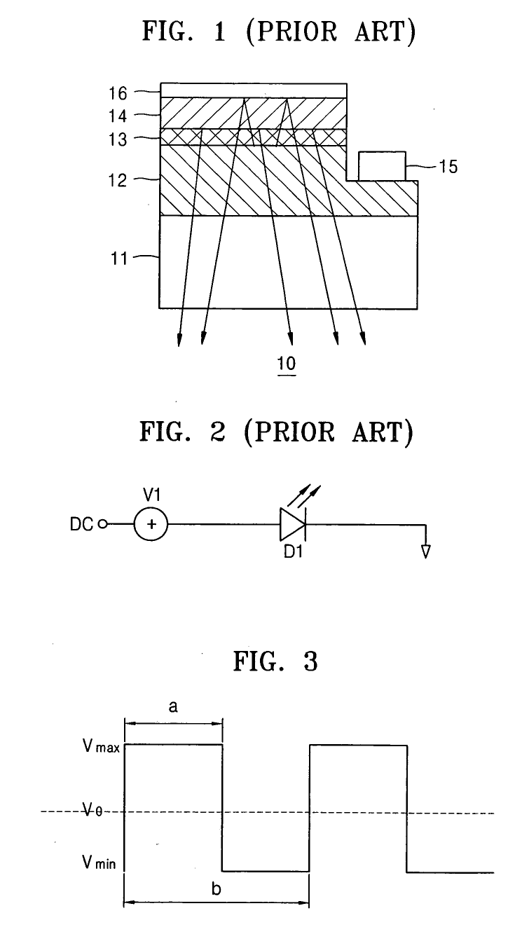

### DETAILED DESCRIPTION OF THE INVENTION

Hereinafter, a method of increasing an optical output of a semiconductor LED, according to an embodiment of the present invention, and the structure and operation of a driving unit of the semiconductor LED will be described in detail with reference to the attached drawings.

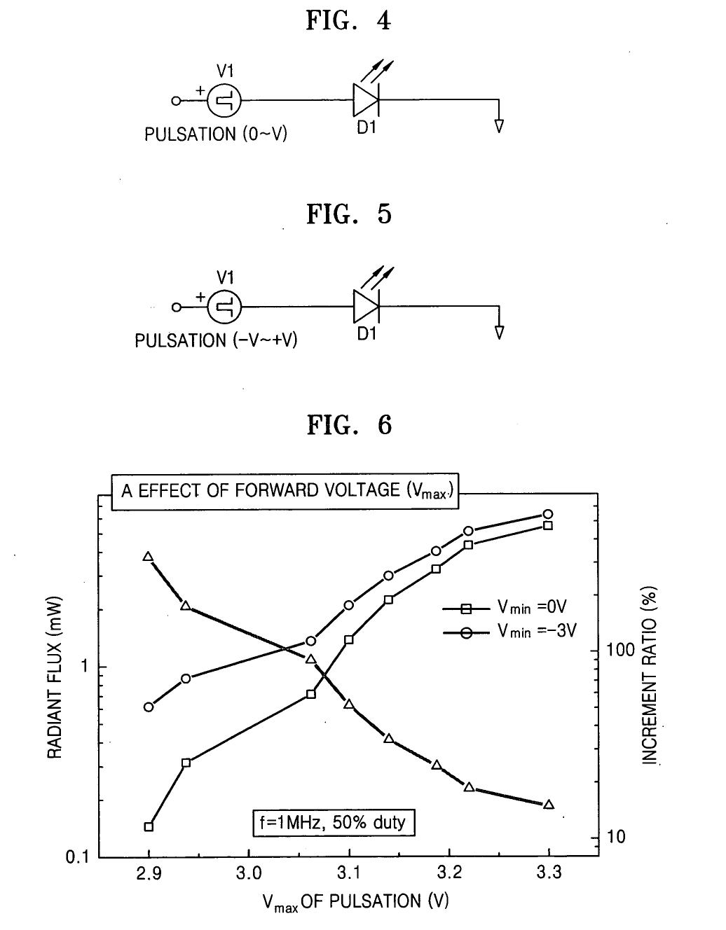

In an experiment, the inventor of the present invention applied a pulsation current in which a forward voltage alternates with a reverse voltage to a semiconductor LED as shown in FIG. 5 in order to solve the above-described problems. Also, the inventor applied a pulsation current in which only a forward voltage is periodically generated without a reverse voltage to the same semiconductor LED as shown in FIG. 4 in order to compare the intensities, i.e., optical outputs, of emitted light. The semiconductor LED used in this experiment was a UV LED lamp which emits light having a wavelength of 402 nm, and a duty ratio of the pulsation current was 50%. Here, as can be seen in FIG. 3, the duty ratio refers to the ratio (a/b) of time a for which a forward voltage is applied, to the total period b.

As a result of the above experiment, as shown in FIG. 6, when a pulsation current in which a forward voltage alternates with a reverse voltage was applied, the optical output of the semiconductor LED was improved. As shown in FIG. 6, a line graph marked with “o” denotes an optical output when the pulsation current includes a reverse voltage of −3V, a line graph marked with “□” denotes an optical output when the pulsation current does not include a reverse voltage, and a line graph marked with “Δ” denotes a ratio of an optical output in two cases. As can be seen in FIG. 6, when the forward voltage is 2.9V, the optical output is more improved when the pulsation current includes the reverse voltage than when the pulsation current does not include the reverse voltage. Also, the optical output slowly increases with a gradual increment of the forward voltage. In this case, the optical output is still higher when the pulsation current includes the reverse voltage than when the pulsation current does not include the reverse voltage. In general, the semiconductor LED is driven by a voltage of about 3.0V to 3.2V. Thus, the optical output can be sufficiently improved within the range between 3.0V and 3.2V.

The improvement efficiency of the optical output of the semiconductor LED observed when the pulsation current includes the reverse voltage may be described with two models, i.e., an electron density variation model and a QCSE model.

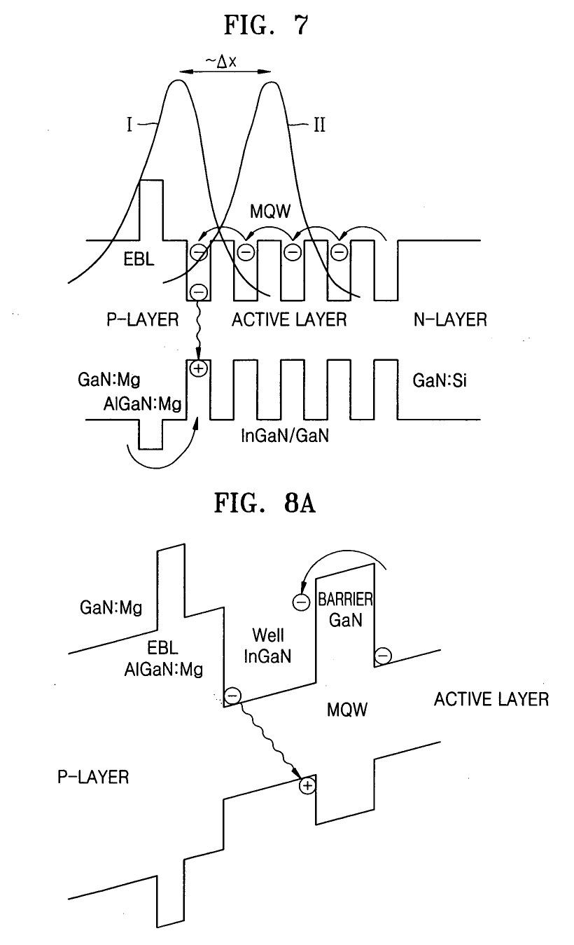

FIG. 7 exemplarily shows an energy band for explaining the principle of the present invention using an electron density variation model. Referring to FIG. 7, an upper energy band denotes a conductive band, and a lower energy band denotes a valence band. Also, a p-type semiconductor layer is located to the left of the energy band, an n-type semiconductor layer is located to the right of the energy band, and an active layer is located in the center of the energy band. As shown in FIG. 7, the active layer has a multiple quantum well (MQW) structure. The p-type semiconductor layer may be formed of, for example, GaN:Mg, and the n-type semiconductor layer may be formed of, for example, GaN:Si. In a case of the active layer having the MQW structure, for example, a quantum well layer may be formed of InGaN, and then a barrier layer may be formed of GaN. An electron blocking layer (EBL) may be formed of, for example, AlGaN:Mg to prevent electrons from penetrating into the p-type semiconductor layer.

In this structure, when (−) voltage is applied to the n-type semiconductor layer, and (+) voltage is applied to the p-type semiconductor layer, electrons excited from the n-type semiconductor layer go over an energy barrier of the conductive band and transfer toward the p-type semiconductor layer via the active layer. Also, holes of the p-type semiconductor layer transfer toward the n-type semiconductor layer via the active layer in the valence band. Here, electrons in the quantum well of the active layer transit and thus re-combined with the holes. As a result, as much light as an energy gap between the conductive band and the valence band is emitted. However, as previously described, the mobility of the holes is much lower than that of the electrons, and the conductivity of the p-type semiconductor layer is low. Thus, the distribution density of the electrons in an equilibrium state is biased toward the p-type semiconductor layer as shown with a curve marked with “I.” This phenomenon may easily occur in a nitride-based semiconductor LED. Thus, light is emitted not from the entire area of the active layer but from the border with the p-type semiconductor layer. As a result, internal quantum efficiency is reduced, which deteriorates the optical output.

Here, when the reverse voltage is periodically applied according to the method of present invention, as shown with a curve marked with “II” of FIG. 7, the distribution density of the electrons in an equilibrium state is moved toward the n-type semiconductor layer in comparison with the case of the pulsation current not including the reverse voltage. This is because the electrons fail to move toward the p-type semiconductor layer but is attracted toward the n-type semiconductor layer due to a positive voltage applied to the n-type semiconductor layer. Thus, light is uniformly emitted from the entire area of the active layer in comparison with the case of the pulsation current not including the reverse voltage. As a result, internal quantum efficiency is increased, which improves the optical output.

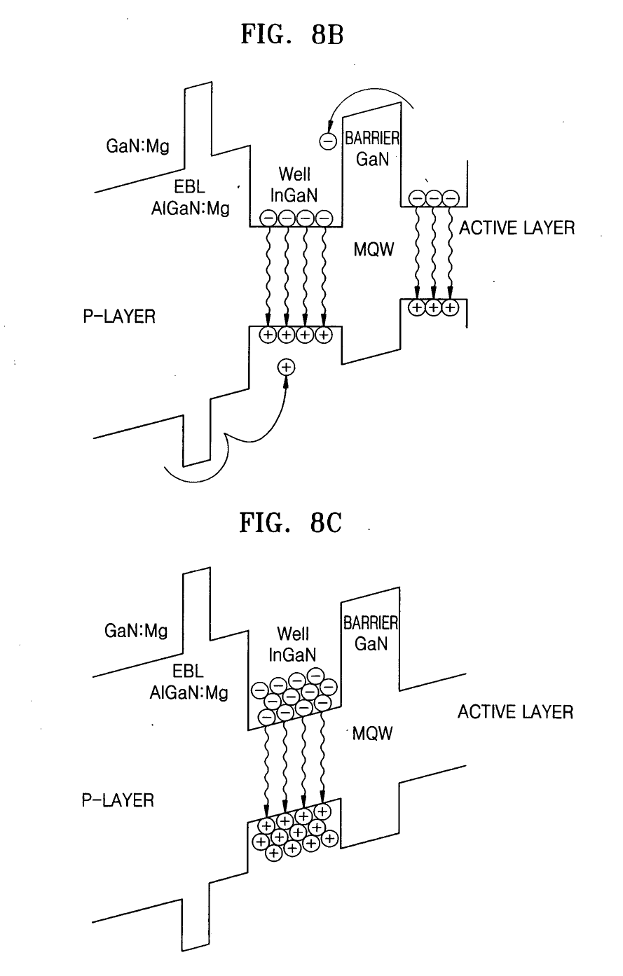

FIGS. 8A through 8C show an energy band for explaining the principle of the present invention using the QCSE model. The energy band is horizontally shown in FIG. 7. However, as shown in FIG. 8A, the energy band is substantially inclined the n-type semiconductor layer toward the p-type semiconductor layer due to a spontaneous polarization effect (SPE) caused by an internal strain and the forward voltage. In this case, when (−) voltage is applied to the n-type semiconductor layer, and (+) voltage is applied to the p-type semiconductor layer, the following phenomenon occurs. As shown in FIG. 8A, the electrons going over the n-type semiconductor layer are located in the lowest part of the quantum well. Similarly, the holes going over the p-type semiconductor layer are located in the highest part of the quantum well. Thus, a distance that the electrons proceed to re-combine with the holes becomes longer, due to which a local separation occurs between the electrons and the holes. This phenomenon is called a “stark effect.” As a result, the re-combination of the electrons with the holes becomes difficult, which lowers the internal quantum efficiency of the active layer and deteriorates the optical output.

In this state, when (+) voltage is applied to the n-type semiconductor layer, and (−) voltage is applied to the p-type semiconductor layer, as shown in FIG. 8B, the bottom of the quantum well becomes level. Thus, when the reverse voltage is periodically applied, the stark effect is partly reduced. As a result, the electrons are freed from the quantum well, which allows the internal quantum efficiency of the active layer to increase and the optical output to improve.

According to the principles of the electron density variation model and the QCSE model, the cause of a reduction in an increment ratio of the optical output of the present invention with an increase in the forward voltage may be explained from the result of the experiment of the FIG. 6. First, according to the QCSE model, the number of the electrons, which transfer from the n-type semiconductor layer to the active layer, increases with an increment in a voltage. As shown in FIG. 8C, a larger number of electrons then exist in the quantum well in the active layer. As a result, the stark effect caused by the location of the electrons in the lowest part of the quantum well is nearly offset, and it takes almost the same effect as that the bottom of the quantum well becomes level. Also, according to the electron density variation model, when the number of electrons, which transfer from the n-type semiconductor layer to the active layer, increases, the number of electrons to be moved by the reverse voltage increases. Thus, the magnitude of Δx of FIG. 7 gets smaller. Therefore, the optical output cannot be sufficiently improved.

Also, according to the principles of the electron density variation model and the QCSE model, the results of the follow experiments can be properly explained.

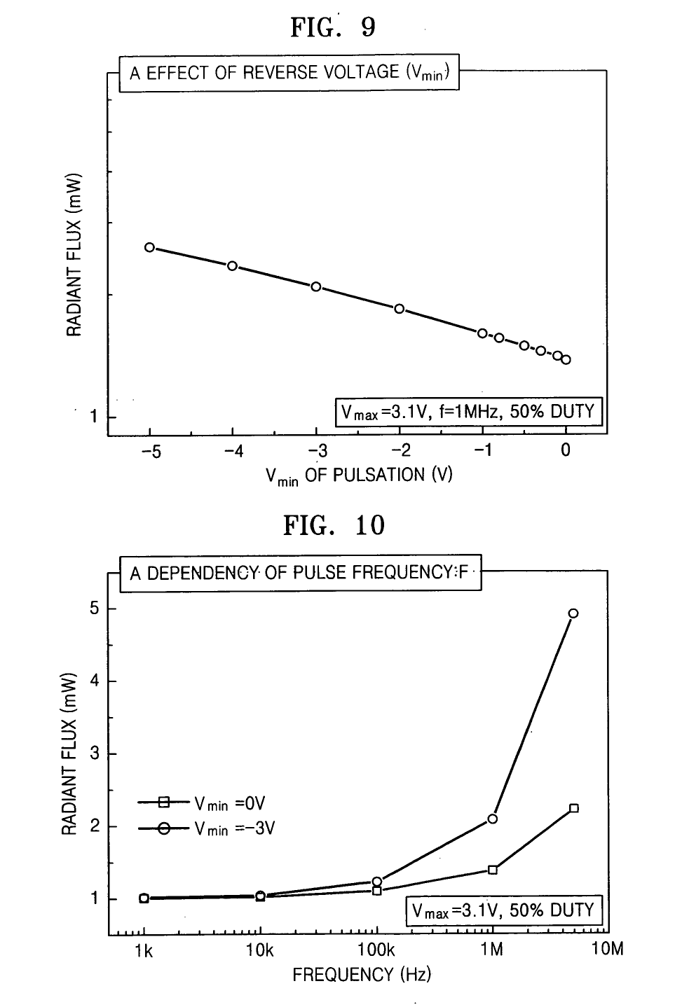

FIG. 9 is a graph for showing variations of an optical output of the semiconductor LED with respect to the magnitude of a reverse voltage. Here, the magnitude of a forward voltage was fixed to 3V, a frequency of a pulsation current was 1 MHz, and a duty ratio of the pulsation current was 50%. The optical output of the semiconductor LED was measured by varying the magnitude of the reverse voltage from 0V to −5V. As a result, as can be seen in FIG. 9, the optical output of the semiconductor LED increases with an increase in the magnitude of the reverse voltage. According to the electron density variation model, the increase in the magnitude of the reverse voltage causes a force acting on electrons toward the n-type semiconductor layer to increase. Thus, the distribution density of the electrons is moved to the center of the active layer. As a result, light is further uniformly emitted from the entire area of the active layer, which improves the optical output. Also, according to the QCSE model, the bottom of the quantum well becomes more level with an increase in the reverse voltage. Thus, a reduction range of the stark effect increases. As a result, the internal quantum efficiency of the active layer and the optical output can improve.

As described above, the optical output of the semiconductor LED increases with an increase in the magnitude of the reverse voltage. Thus, according to the present invention, a reverse voltage of more than at least 0.1V is periodically applied to increase the optical output of the semiconductor LED. Also, as shown in FIG. 6, the increment ratio of the optical output decreases with an increase in the forward voltage. Thus, in this case, the magnitude of an absolute value of the reverse voltage may be set to be larger than the magnitude of an absolute value of the forward voltage to overcome the reduction in the increment ratio of the optical output. However, the magnitude of the reverse voltage must not be larger than that of a breakdown voltage of the semiconductor LED. Since the breakdown voltage of the semiconductor LED is generally about −20V, the maximum reverse voltage may be about −20V.

FIG. 10 is a graph for showing variations of the optical output of the semiconductor LED with respect to variations of a frequency of a pulsation current when the pulsation current includes a reverse voltage or does not include the reverse voltage. Here, a line graph marked with “o” denotes an optical output when the pulsation current includes a reverse voltage of −3V, and a line graph marked with “□” denotes an optical output when the pulsation current does not include the reverse voltage (a minimum voltage is 0V). A forward voltage was fixed to 3.1V, and a duty ratio was 50%. As shown in FIG. 10, when the frequency of the pulsation current is 1 KHz, the optical output of the semiconductor LED increases only a little. However, the increment ratio of the optical output increases with an increase in the frequency of the pulsation current. This phenomenon may be described with the reason why the re-arrangement of electron distribution in the active layer becomes equal to a general DC when one period gets longer.

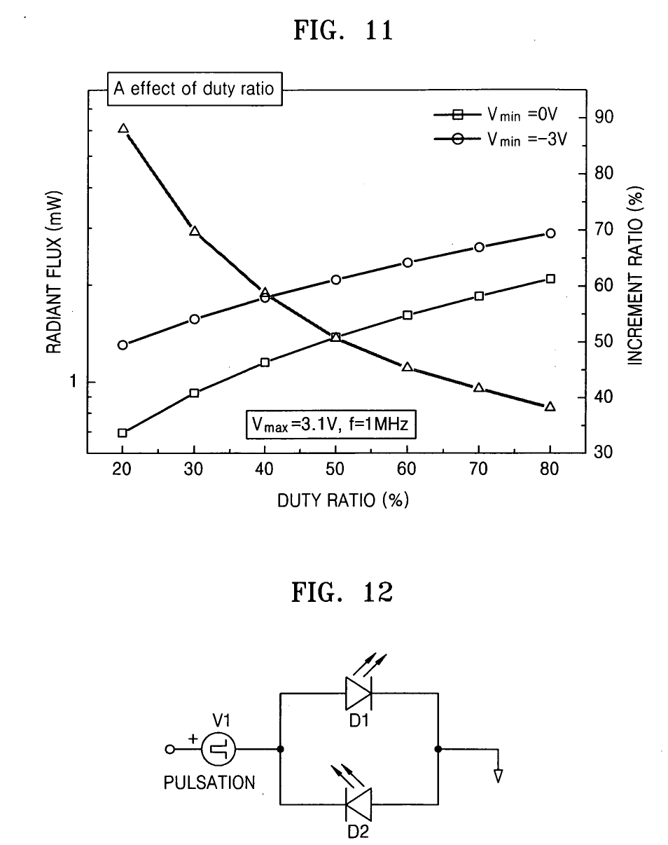

FIG. 11 is a graph for showing variations of the optical output of the semiconductor LED with respect to a duty ratio of a pulsation current when the pulsation current includes a reverse voltage or does not include the reverse voltage. Here, a line graph marked with “o” denotes an optical output when the pulsation current includes a reverse voltage −3V, and a line graph marked with “□” denotes an optical output when the pulsation current does not include the reverse voltage (a minimum voltage is 0V). A forward voltage was fixed to 3.1V, and a frequency of the pulsation current was 1 MHz. As can be seen in FIG. 11, as the duty ratio is small, the increment ratio of the optical output increases. As the duty ratio is large, the increment ratio of the optical output decreases. When the duty ratio increases, during one period, an amount of a forward current increases, while an amount of a reverse current decreases. Therefore, when the duty ratio is large, the number of electrons transferring from the n-type semiconductor layer to the active layer increases, but the time required for re-distributing the electrons in the n-type semiconductor layer to uniformly distribute the electrons in the active layer is not sufficient. However, when the duty ratio is small, the number of electrons transferring from the n-type semiconductor layer to the active layer is small, and the time required for re-distributing the electrons in the n-type semiconductor layer to uniformly distribute the electrons in the active layer is sufficient. As a result, the optical output greatly increases. Accordingly, a duty ratio of a pulsation current applied to the semiconductor LED is preferably within a range between 10% and 90%.

The principle of the present invention and an increase in the optical output of the semiconductor LED according to the principle of the present invention have been described in detail. According to the detailed description, in the present invention, the optical output can be greatly increased without changing the structure of the semiconductor LED. However, light is not emitted when a reverse voltage is applied to the semiconductor LED. Thus, the optical output may be seen as decreasing at an overall time.

FIG. 12 shows a driving unit of the semiconductor LED of the present invention. As shown in FIG. 12, the driving unit of the semiconductor LED includes at least two semiconductor LEDs, i.e., first and second semiconductor LEDs D1 and D2, and a voltage applying unit which applies a pulsation current in which a forward voltage alternates with a reverse voltage to the two semiconductor LEDs. Here, the two LEDs are connected in parallel so that their polarity directions are opposite to each other.

In this structure, when the voltage applying unit generates a positive voltage, the first semiconductor LED D1 emits light. Here, a reverse voltage is applied to the second semiconductor LED D2, and thus electrons in the active layer are re-arranged. According to the QCSE model, the quantum well in the active layer becomes level. Thereafter, when the voltage applying unit generates a negative voltage, the second semiconductor LED D2 emits light. Here, a reverse voltage is applied to the first semiconductor LED D1, and thus the electrons in the active layer are re-arranged. Similarly, according to the QCSE model, the quantum well in the active layer becomes level. In the driving unit of the present invention, two semiconductor LEDs alternately emit light. Thus, the optical output increases at an overall time. However, in this case, it is preferable that a forward voltage has the same magnitude as a reverse voltage and a duty ratio is 50% so that the two semiconductor LEDs produce the same optical output.

As described above, in a method of increasing an optical output of a semiconductor LED using a pulsation current and a driving unit of the semiconductor LED using the method, according to the present invention, when the same current is applied, an optical output can greatly increase without basically changing the structure of the semiconductor LED. Thus, emission efficiency of the semiconductor LED can be considerably improved using a method of applying a voltage according to the present invention. Moreover, the semiconductor LED is periodically turned off in comparison with a case of a continuously flowing continuous current. Thus, an amount of heat generated from the semiconductor LED is reduced. As a result, the stability of the semiconductor LED can be greatly improved.

Also, since the pulsation current is applied to the semiconductor LED, an alternating current (AC)-DC converter does not need to be used when a home AC is used. Furthermore, the amount of heat generated from the semiconductor LED is small. Thus, in a case where the semiconductor LED is applied to a large capacity display device, higher luminous efficiency can be obtained.

The semiconductor LED such as an LED has bee mainly described, but the principle of the present invention can also be applied to a solid-sate lighting technique.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of increasing an optical output of a semiconductor light-emitting device, comprising:
applying a pulsation current in which a forward voltage alternates with a reverse voltage to the semiconductor light-emitting device comprising an n-type semiconductor layer, an active layer, and a p-type semiconductor layer.

2. The method of claim 1, wherein an absolute value of the reverse voltage applied to the semiconductor light-emitting device is larger than 0.1V.

3. The method of claim 1, wherein a frequency of the pulsation current is at least 1 KHz.

4. The method of claim 1, wherein a duty ratio of the pulsation current is within a range between 10% and 90%.

5. The method of claim 1, wherein an absolute value of the reverse voltage applied to the semiconductor light-emitting device is larger than an absolute value of the forward voltage.

6. The method of claim 5, wherein a magnitude of the reverse voltage is smaller than a magnitude of a breakdown voltage of the semiconductor light-emitting device.

7. The method of claim 1, wherein a pulsation current is applied to at least two semiconductor light-emitting devices which are connected in parallel so as to have opposite polarity directions.

8. A driving unit of a semiconductor light-emitting device comprising:
a semiconductor light-emitting device comprising an n-type semiconductor layer, an active layer, and a p-type semiconductor layer; and
a voltage applying unit which applies a pulsation current in which a forward voltage alternates with a reverse voltage to the semiconductor light-emitting device.

9. The driving unit of claim 8, wherein an absolute value of the reverse voltage applied to the semiconductor light-emitting device is larger than 0.1 V.

10. The driving unit of claim 8, wherein a frequency of the pulsation current is at least 1 KHz.

11. The driving unit of claim 8, wherein a duty ratio of the pulsation current is within a range between 10% and 90%.

12. The driving unit of claim 8, wherein an absolute value of the reverse voltage applied to the semiconductor light-emitting device is larger than an absolute value of the forward voltage.

13. The driving unit of claim 12, wherein a magnitude of the reverse voltage is smaller than a magnitude of a breakdown voltage of the semiconductor light-emitting device.

14. A driving unit of a semiconductor light-emitting device comprising:
a plurality of semiconductor light-emitting devices comprising n-type semiconductor layers, active layers, and p-type semiconductor layers; and
a voltage applying unit which applies a pulsation current in which a forward voltage alternates with a reverse voltage to the plurality of semiconductor light-emitting devices,
wherein at least two of the plurality of semiconductor light-emitting devices are connected in parallel so as to have opposite polarity directions.

15. The driving unit of claim 14, wherein a frequency of the pulsation current is at least 1 KHz.

16. The driving unit of claim 14, wherein an absolute value of the reverse voltage applied to the light-emitting devices is substantially equal to an absolute value of the forward voltage.

17. The driving unit of claim 14, wherein a duty ratio of the pulsation current applied to the semiconductor light-emitting devices is substantially 50%.
